(19) United States
(12) Patent Application Publication
(10) Pub. No.: US 2006/0139185 A1
(43) Pub. Date: Jun. 29, 2006

(54) Input device for a computer system that utilizes ambient light, and a method of manufacturing the same

(76) Inventors: Pierre Bonnat, Las Vegas, NV (US); Adam M Howard, Las Vegas, NV (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/530,939

(22) PCT Filed: Aug. 12, 2003
(86) PCT No.: PCT/US03/25421

§ 371 Date: Dec. 22, 2005

Related U.S. Application Data
(63) Continuation-in-part of application No. 10/402,729, filed on Mar. 28, 2003.
(60) Provisional application No. 60/402,994, filed on Aug. 12, 2002.
(60) Provisional application No. 60/435,626, filed on Dec. 19, 2002.
(60) Provisional application No. 60/368,602, filed on Mar. 29, 2002.
(60) Provisional application No. 60/378,573, filed on May 6, 2002.
(60) Provisional application No. 60/402,994, filed on Aug. 12, 2002.

(51) Int. Cl. H03M 11/00; H03K 17/94

(52) U.S. Cl. 341/21; 341/31

(57) ABSTRACT

An input device, to provide input to a computer system, includes a body defining multiple fluid channels. A movable element is located within each of the fluid channels so as to be movable and responsive to a fluid flow through the respective fluid channel. A light sensor is furthermore associated with each movable element, such that movement of the movable element varies an intensity of light to which the respective light sensor is exposed. The input device generates an input signal in accordance with the intensity of the light to which at least one light sensor of the input device is exposed.

This application claims the benefit of U.S. Provisional Applications Nos. 60/402,994, filed Aug. 12, 2002, and 60/435,626, filed Dec. 19, 2003 and U.S. Utility application Ser. No. 10/402,729, filed Mar. 28, 2003, each of the above applications being incorporated herein by reference.

### FIELD OF THE INVENTION

The present invention relates in general to providing input to a computer system and, in one exemplary embodiment, to an input device for a computer system that utilizes ambient light to control generation of an input signal.

### BACKGROUND OF THE INVENTION

The mouse, in addition to the traditional keyboard, is one of the most widely deployed peripheral devices for providing input to a computer system. A mouse is specifically suited to facilitating user navigation of a user interface that is presented by an application executing on the relevant computer system, and is typically utilized to control movement of a cursor over a presented user interface.

From a mechanical viewpoint, a mouse typically includes some mechanism for detecting movement of the mouse over a surface. For example, such a mechanism may be a ball that is rotatably mounted to an undersurface of the mouse, or an optical arrangement that is able to detect movement of the mouse over a surface. In addition to the movement detecting mechanism, a mouse also typically includes a processor that translates detected movement into one or more control signals, which are recognized by a communication protocol (e.g., RS 232) of a port of the computer system to which the mouse is coupled.

A mouse may furthermore include a user-selection mechanism (e.g., a button) that is sensitive to a user input action (e.g., a depression of the button) to generate a further control signal (e.g., a selection signal) to the computer system.

To enable a mouse to interact with a computer system, the computer system typically also executes control software, in the form of a driver, that provides application software with information concerning the state and status of a mouse (e.g., movement and user-selection information), so as to enable the application software to carry out actions responsive to these inputs.

A mouse is typically operated by a user moving the mouse over a surface, or moving a component (e.g., a ball rotatably mounted within the mouse). It will be appreciated that such movement of a mouse or a component of the mouse typically requires a hand movement by a user. However, in certain circumstances, it may be impractical, inconvenient or impossible for a user to directly and physically move the mouse, or a component thereof.

### SUMMARY OF THE INVENTION

According to one aspect of the present invention, there is provided an input device to provide input to a computer system. The input device includes body defining a fluid channel. A movable element is located to be movable responsive to a fluid flow through the fluid channel. A light sensor is located such that movement of the movable element varies an intensity of light with which the light sensor is illuminated, the light sensor being to generate an input signal in accordance with the intensity of the light with which the light sensor is illuminated.

The body may define a plurality of fluid channels, and the input device may further include a plurality of movable elements, each of the plurality of movable elements being associated with a respective one of the plurality of fluid channels and being movable responsive to a fluid flow through the respective one of the plurality of channels. The input device may also include a plurality of light sensors, each of the plurality of light sensor being associated with a respective one of the plurality of movable elements such that movement of the respective movable element varies an intensity of light with which the light sensor is illuminated, each of the plurality of light sensors being able to generate one of a plurality of input signals in accordance with the intensity of light with which the respective light sensor is illuminated, each of the plurality of input signals operationally providing a differentiated input to a computer system.

In one embodiment, the movable element is located within the fluid channel so as to be movable responsive to the fluid flow therethrough.

The movable element may be secured to the body at a fixed end thereof so as to be pivotably movable within the fluid channel.

The body may also define an inlet opening and an exhaust opening for the fluid channel.

In one embodiment, the body defines an opening through which the light sensor is operationally illuminated with ambient light, and the light sensor is located such that the movement of the movable element varies an intensity of ambient light with which the light sensor is illuminated.

A light channel may operationally channel the ambient light through the opening to illuminate the light sensor. A light channel may include a light-conductive material, such as a fiber optic thread.

In one embodiment, a window is located in the opening through which the light sensor is operational exposed to the ambient light.

One embodiment of the input device may also include an artificial light source operationally to supplement the ambient light.

An ambient light sensor may operationally sense an intensity of the ambient light, and the input device may include a controller to activate the artificial light sensor when the intensity of the ambient light, as sensed by the ambient light sensor, is below a predetermined minimum. The artificial light source may, in one embodiment, operationally supplement the ambient light in accordance with a measured intensity of the ambient light. The artificial light source may operationally also supplement the ambient light so as to illuminate the light sensor with a combined intensity above a predetermined minimum intensity.

According to a second aspect of the present invention, there is provided an input device to provide input to a computer system. The input device includes plurality of light sensors, each to generate a discrete output, and arranged operationally to be illuminated by ambient light. A controller, coupled to each of the plurality of light sensors, operationally generates an input to a computer system based on at least one discrete output received from the plurality of light sensors.

The device includes, in one embodiment, a body to which each of the plurality of light sensors is attached. Each of the plurality of light sensors may be accommodated within the body. The body may furthermore define at least one opening through which at least one of the plurality of light sensors is operationally illuminated by the ambient light.

A light channel may be provided through which the ambient light is operationally channelled, through the at least one opening, to illuminate the at least one of the plurality of light sensors. The light channel may a light-conductive material, such as fiber optic thread.

Each of the plurality of light sensors may, in one exemplary embodiment, be housed within a respective chamber defined within the body, and each of the chambers may be provided with an opening through which a respective one of the plurality of light sensors is operationally illuminated by the ambient light.

According to further aspect of the present invention, there is provided a method of manufacturing an input device according to any one of the preceding claims.

According to a yet further aspect of the present invention, there is provided kit including an input device according to any one of the preceding claims, and a computer system.

Other features of the present invention will be apparent from the accompanying drawings and from the detailed description that follows.

### BRIEF DESCRIPTION OF THE DRAWINGS

The present invention is illustrated by way of example and not limitation in the figures of the accompanying drawings, in which like references indicate similar elements and in which:

FIGS. 1A-1F are perspective, and sectional, views of a user input device, according to one exemplary embodiment of the present invention, and illustrate the fluid channel or passages defined through a body of the input device.

FIG. 2 is a sectional view illustrating the location of movable elements within the fluid channels that are defined within the body of the input device, according to an exemplary embodiment.

FIG. 3 is a perspective view illustrating a pivot movement of a movable element within a fluid channel responsive to a fluid flow between an inlet and an outlet of the relevant fluid channel, according to one exemplary embodiment of the present invention.

FIG. 4 shows a series of side views that depict the movement of a movable element within a fluid channel of the input device, responsive to a fluid flow through the relevant channel, according to an exemplary embodiment of the present invention.

FIG. 5 is a perspective view of a comb of movable segments that may conveniently be manufactured for insertion into the body of an input device, according to one embodiment of the present invention.

FIGS. 6A-6B illustrate the location of light sensors within the body of an input device, according to one exemplary embodiment of the invention, and also the location of openings through which these light sensors may be illuminated by ambient light.

FIGS. 7A-7B are plan and perspective views of an alternative embodiment of an input device, where the locations of the openings through which the light sensors are illuminated are different from those illustrated in FIGS. 6A-6B.

FIG. 8 illustrate how a hand gesture of a user may be utilized to interfere with ambient light passing through an opening of the body of the input device, the relevant user gesture to be sensed by the input device, according to one exemplary embodiment of the present invention.

FIG. 9 is a perspective view of a user input device, according to yet a further exemplary embodiment of the present invention, that includes a bifurcated fiber optic thread for channeling both ambient and artificial light to a light sensor.

FIG. 10 is a block diagram illustrating electronic components of a user input device, according to an exemplary embodiment of the present invention, that uses ambient light in the generation of input signals to a computer system

FIG. 11 illustrates a series of gesture-based interactions that may be performed by users, utilizing various embodiments of the present invention.

FIG. 12 is a perspective view of the mounting of an input device, according to one exemplary embodiment of the present invention, to a headset so as to allow a user to blow and suck air through the fluid channels of the input device, thereby to generate input signals to a computer system.

FIG. 13 is a block diagram illustrating a machine, in the exemplary form of a computer system, for executing a set of instructions that, when executed by the machine, cause the machine to perform many of the methodologies described herein.

### DETAILED DESCRIPTION

An input device, for a computer system, that utilizes ambient light to generate input signals to the computer system, and a method of manufacturing the same are described. In the following description, for purposes of explanation, numerous specific details are set forth in order to provide a thorough understanding of the present invention. It will be evident, however, to one skilled in the art that the present invention may be practiced without these specific details.

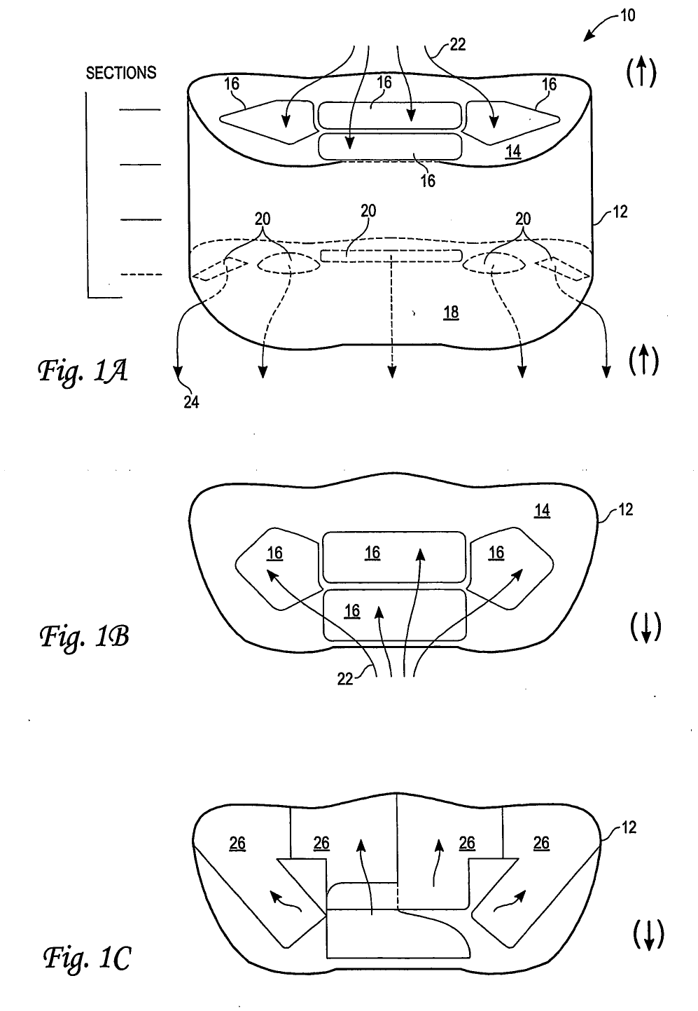

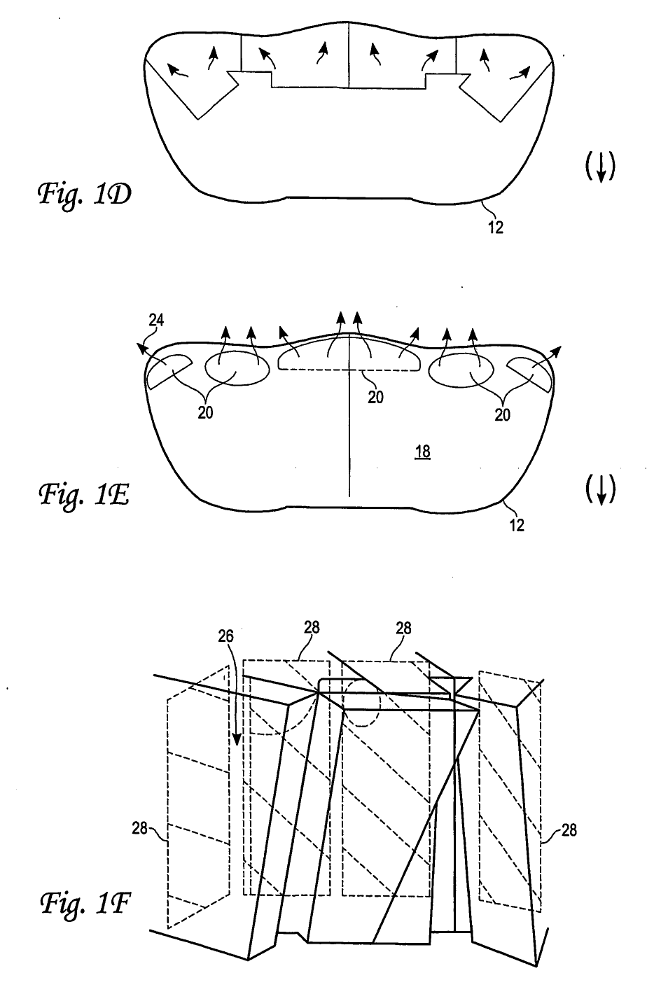

FIGS. 1A-1F show perspective and sectional views of an input device 10, according to an exemplary embodiment of the present invention, that includes a body 12 through which a series of fluid channels are defined, movable elements that are located within the fluid channels, and light sensors that are responsive to an ambient light received into the body 12 through windows defined therein, and optionally also to artificial light that may be generated by the input device 10 itself. The intensity of the light with which the light sensors are illuminated may, in one embodiment, be varied by the movement of the movable elements within the fluid channels. As will be discussed in further detail below, the input device 10 is responsive to a user action (e.g., a blowing or a sucking action, or a gesture or movement of the user) to generate input signals to a computer system.

The exemplary input device 10 illustrated in FIGS. 1A-1F enables a user to generate the input signals to a computer system by creating a fluid flow, in the exemplary form of an air movement or current, through a number of fluid channels defined in the body 12 of the input device 10. A further embodiment of an input device 10, utilizing which a user can generate input signals by performing gestures to interfere with the ambient light that illuminates the input device 10, will be described in further detail below.

Turning specifically to FIGS. 1A-1F, FIG. 1A illustrates an upper surface 14 of the body 12 having a number of first openings 16 defined therein, each of the first openings 16 providing a fluid inlet (or outlet) to a respective fluid channel 26 that is defined by the body 12. A lower surface 18 of the body 12 has a number of second openings 20 defined therein, each of the second openings 20 providing a fluid outlet (or inlet) for at least one fluid channel 26. FIG. 1A illustrates the movement of a fluid (e.g., air resulting from a blowing action performed by a user) entering the first openings 16, this fluid movement being indicated by the arrow 22. FIG. 1A also illustrates the outlet of the air from the second opening 20, this movement of the air being indicated by the arrow 24.

FIG. 1B provides a plan view of the upper surface 14, and illustrates the location and shape of the first openings 16, according to one exemplary embodiment of the present invention. Similarly, FIG. 1E illustrates a plan view of the lower surface 18 of the body 12, and illustrates the shape and location of the second openings 20, according to the exemplary embodiment. FIGS. 1C and 1D provide cross sectional views of the body 12, showing the shape of the four fluid channels 26 defined by the body 12.

FIG. 1F is a perspective view showing further detail regarding the shapes of the exemplary fluid channels 26 defined within the body 12. It will be noted that the fluid channels 26 taper from the relatively larger first opening 16 to the relatively smaller second opening 20, thus seeking to ensure that pressure within the fluid channel 26 at least remains the same, or possibly increases, towards the second opening 20 thereof.

While the fluid flow illustrated in FIGS. 1A-1F is shown to be from the first openings 16 to the second openings 20, as a result of a blowing action by a user for example, a fluid flow in the opposite direction could be caused by, for example, a user performing a sucking action at or adjacent the first openings 16, thus causing a fluid flow in the direction opposite to the directions indicated by the arrows 22 and 24.

In one embodiment of the present invention, movable elements 28 are located within each of the four fluid channels 26 defined in the body 12, these movable elements 28 being movable responsive to a fluid flow through a respective fluid channel 26. The exemplary embodiment also proposes locating light sensors within each of the fluid channels 26 such that movement of a movable element within a respective fluid channel 26 causes a variance in an amount (or an intensity) of light with which the light sensor is illuminated. This variation in the illumination of the light sensor is then converted by the relevant sensor to a signal that is provided to a controller, which in turn may utilize the signal in the generation of an input signal to a computer system.

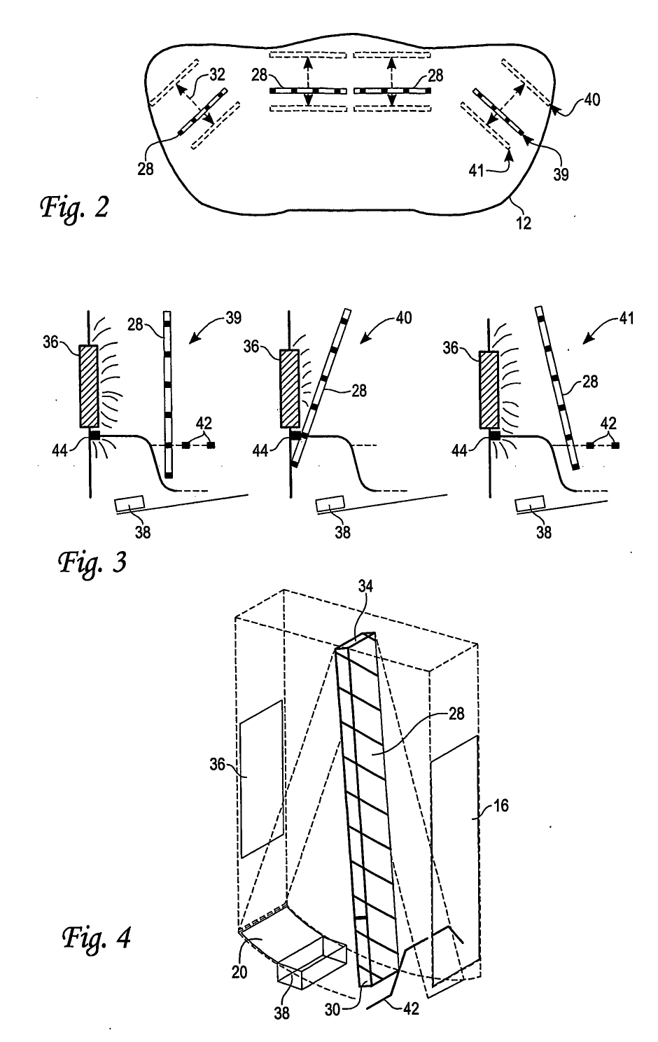

FIG. 2 is a plan view illustrating the location of a movable element 28 within each of the fluid channels 26, and illustrates the extent of motion of a free end 30 of each of the movable elements 28, the extent of motion being indicated by the arrows 32. Specifically, each movable element 28 is shown to be movable between a first position 39, a second position 40, and a third position 41 within a respective fluid channel 26.

FIG. 3 illustrates a sequence of side views showing the movement of the movable segment 28 between first, second and third positions 39, 40 and 41. FIG. 3 additionally illustrates the inclusion of an artificial light source 44 within the fluid channel 26. In one exemplary embodiment of the present invention, the artificial light source 44 may be a Light Emitting Diode (LED). As will be described in further detail below, the artificial light source 44 may be activated by a controller when it is determined that ambient light with which the sensor 38 is illuminated is below a predetermined minimum. Specifically, a controller located within the input device 10 may receive a signal from one or more light sensors 38 (or a dedicated ambient light sensor) that allows the controller to determine the intensity of the ambient light, and to activate the artificial light source 44 when the intensity of the ambient light is determined to be below the predetermined minimum. In one embodiment, the controller may operate to control the intensity (or amount) of the artificial light that emanates from the artificial light source 44 so as to supplement the ambient light. This ensures that the intensity of the light with which the light sensor 38 is illuminated is maintained within a certain parameters, or above a predetermined minimum intensity. For example, where the intensity of the ambient light is by itself sufficient to ensure proper operation of the sensor 38, the artificial light source 44 may be completely switched off. On the other hand, where ambient light is present, but the intensity thereof is not sufficient to ensure proper operation of the light sensor 38, the artificial light source 44 may be activated to generate an artificial light that, when combined with the present ambient light, has an intensity sufficient to ensure proper operation of the light sensor 38. Where ambient light is substantially absent (e.g., when operating in the dark), the intensity of the artificial light generated by the artificial light source 44 can be increased so that the light sensor 38 is sufficiently illuminated by the artificial light source 44 alone. Accordingly, the artificial light source 44 may be controlled by the controller to supplement the ambient light with which the light sensor 38 is illuminated in accordance with a measured or determined intensity of the ambient light.

FIG. 3 illustrates the artificial light source 44 as being positioned such that the movement of the movable element 28 into the second position 40 also serves to obstruct both the artificial light generated by the source 44, and the ambient light received through the window 36. Accordingly, FIG. 3 shows the artificial light source 44 as being located adjacent to the window 36 within the fluid channel 26.

FIG. 4 is a pictorial view of a movable element 28 located within a fluid channel 26, and shows pivoting movement of the movable element 28 around a fixed end 34 thereof that, in one exemplary embodiment, is secured to the body 12 within a fluid channel 26 having the first and the second openings 16 and 20. The fluid channel 26, as described above, may include a first opening 16 and a second opening 20 by which fluids can enter and exit the fluid channel 26 and cause pivotal movement of the movable member 28 about an axis defined by the fixed end 34 of the movable element 28.

An opening, in the exemplary form of the window 36, is also shown to enable ambient light from outside the body 12 to enter a fluid channel 26. Also shown to be located within the fluid channel 26 is a light sensor 38 that is illuminated by ambient light received into the fluid channel 26 via the window 36 when the movable element 28 is in the first position 39, indicated in solid line, in FIG. 3. However, when the movable element pivots towards the second position 40, indicated in broken line in FIG. 3, it will be appreciated the movable element 28 increasingly obstructs the ambient light to which the sensor 38 is exposed. For example, an air current injected into the fluid channel 26 via the first opening 16 will cause the movable element 28 to pivot about its fixed end 34 and to move from the first position 39 towards the second position 40, progressively reducing the amount of ambient light with which the sensor 38 is illuminated as it moves towards the second position 40. The degree of movement of the movable element 28 may, in one embodiment, be dependent upon the force or pressure exerted by the air current injected into the first opening 16. Accordingly, by controlling the force of the air current inserted into the first opening 16, a user is able to exercise control over the degree to which the sensor 38 is illuminated by ambient light received into the fluid channel 26 via the window 36, and also optionally artificial light received from an artificial light source 44.

One or more contacts, as fully described in a co-pending U.S. Utility application Ser. No. 10/402,729, filed Mar. 28, 2003, may also be incorporated into the input device 10. Specifically, in the exemplary embodiment, the movement of the movable element 28 towards a third position 41, also illustrated in broken line in FIG. 4, causes the closing of a physical contact to thereby register the movement of the movable element 28 into the third position 41. Referring again to FIG. 3, in one exemplary embodiment, contacts 42 may be located on the inside wall of the fluid channel 26, the contacts 42 being activated as the movable element 28 moves into a position adjacent to the relevant contacts 42. In various embodiment of the present invention, the contacts 42 may be brushes, wires, or pin contacts, or may be implemented as switches to enable the sensing of discreet functions (e.g., clicking and other functionalities). It will be appreciated that the movement of the movable element 28 towards the third position 41 may be achieved by causing an air current flow from the second opening 20 towards the first opening 16. Such a current flow may be caused by a user, for example, performing a sucking operation at or adjacent the first opening 16, or by performing a blowing operation at or adjacent to the second opening 20.

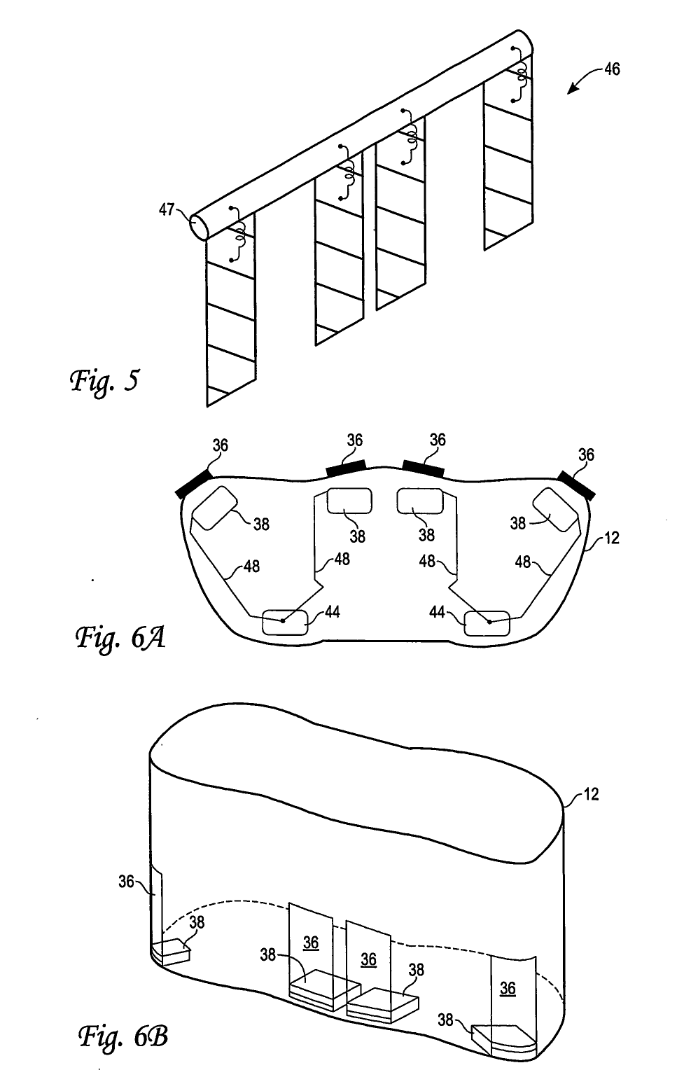

FIG. 5 illustrates an assembly 46 (or comb) of movable elements 28, according to an exemplary embodiment to the present invention, that may conveniently at the manufactured for insertion into the four fluid channels 26. As illustrated, the assembly 46 includes a rod 47 from which the four movable elements depend, and to which the four movable elements 28 are fixedly secured at their respective fixed ends 34. In one embodiment, the rod 47 is constructed of a flexible material so as to allow it to be bent or deformed and to be inserted into a complimentary groove defined within the body 12 of the input device 10. In various embodiments of the present invention, the movable elements 28 may be opaque or have a limited to transparency so as to enable the movable elements 28 to obstruct the transmission of light. The movable elements 28 may be non-transparent and may be movable in two directions. Further, the assembly 46 may include springs or other mechanical systems to bias the movable elements 28 into a particular position, and provide a predetermined degree of resistance to movement in one or more directions.

FIGS. 6A-6b show perspective views providing further details regarding the location of light sensors 38 within the four fluid channels 26 defined within the body 12 of the exemplary input device 10. Specifically, FIG. 6A is a plan view of the body 12 and shows four light sensors 38, each of which is located within a separate fluid channel 26. The body 12 is also shown to define an opening, in the exemplary form of a window 36, within each of the fluid channels 26 so as to expose a respective light sensor 38 to ambient light outside of the body 12. It will be appreciated that the ambient light that is permitted to enter the body 12 through the windows 36 may be natural light, or maybe artificial light (e.g., generated by fluorescent and/or incandescent lights). FIG. 6A also illustrates two artificial light sources 44 from which artificial light is piped by channels, in the exemplary form of a fiber optic thread 48, so that the light sensors 38 may optionally be illuminated by the artificial light. The ends of the fiber optic threads 48 may be located such that the illumination of the light sensors 38 by the artificial light emanating from the fiber optics 48 is controllable by the positioning of a respective movable element 28 within a fluid channel 26. FIG. 6B shows a perspective view of the body 12, and shows the location of the respective windows 36 for allowing the entry of the ambient light into fluid channels 26. The various light sensors 38 may furthermore each be mounted in an angled position within the body 12 so as to optimize illumination of a sensing surface of each of the relevant light sensors 38.

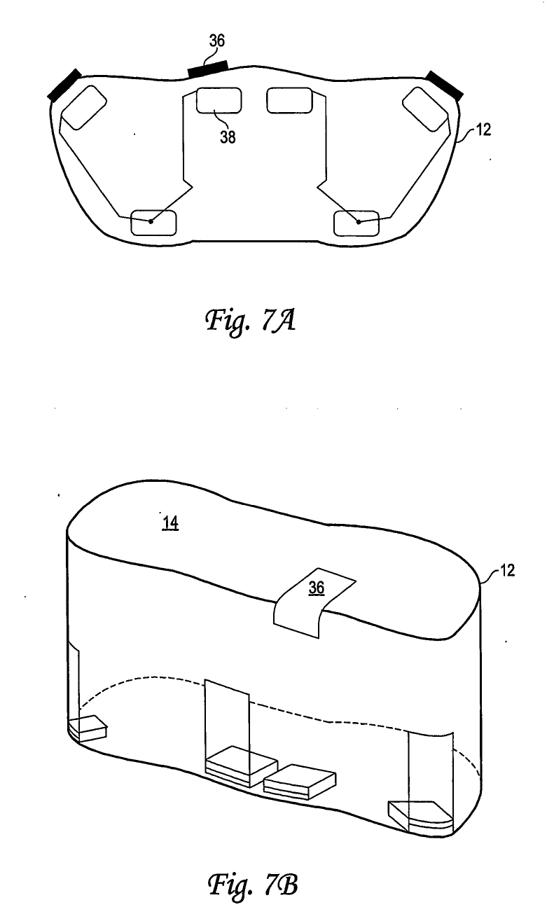

FIGS. 7A and 7B illustrate an alternative embodiment of the present invention, where the windows 36 are defined within the body 12 so as to make the input device 10 particularly suited for gesture-based input. The location of the window 36 adjacent to the upper surface 14, and at a distance from the other windows 36, allows a user to restrict the passage of ambient light through the window 36 without necessarily obstructing the passage of ambient light through the other windows 36. The embodiment shown in FIG. 7B has windows that are sufficiently spaced so as to enable a user conveniently to obstruct or restrict the passage of ambient light through these windows 36, without obstructing the passage of light through any of the other windows 36.

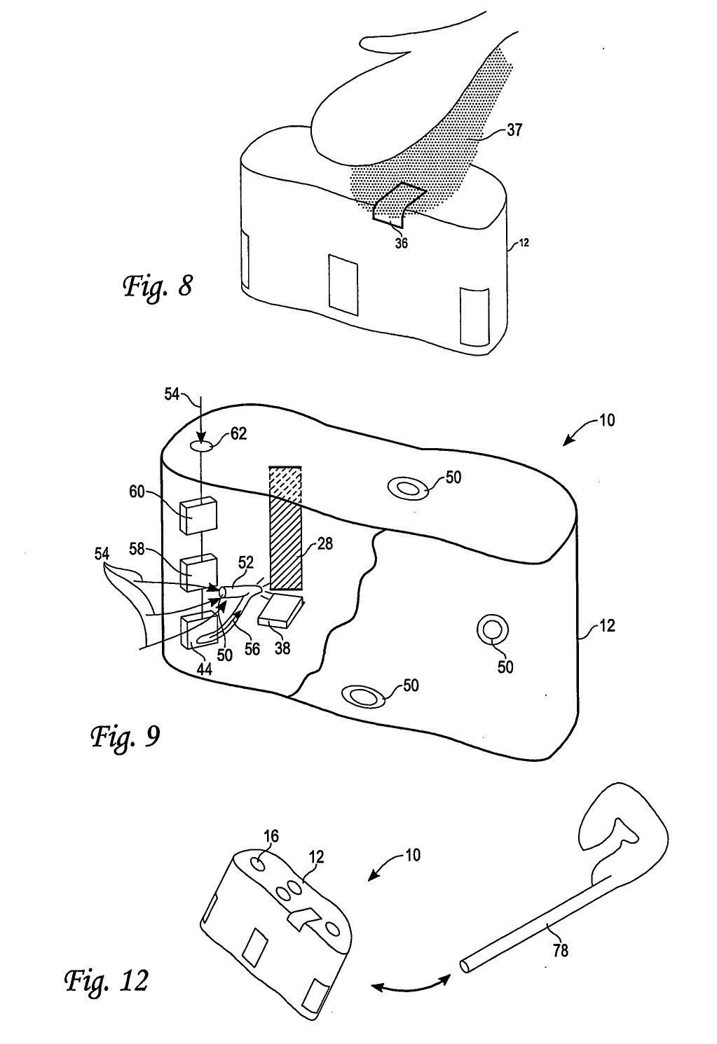

FIG. 8 illustrates a gesture-based interaction by a user with the exemplary embodiment of the present invention illustrates it in FIG. 7B. Specifically, the user is shown to cast a shadow 37 over the window 36, thereby obstructing the passage of ambient light through the window 36 and onto an associated light sensor 38.

FIG. 9 is a perspective view of yet a further exemplary embodiment of an input device 10, according to the present invention. Instead of having the windows 36 discussed above with reference to FIG. 8, a number of openings 50 are defined in body 12 that expose the end of a fiber optic thread 52 that pipes ambient light 54 into the body 12 and directs this ambient light 54 to the sensing surface of a light sensor 38. Again, a movable element 28 may be optionally located within a fluid channel 26 o as to be movable relative to the light sensor 38 so as to obstruct the illumination of the light sensor 38 by the ambient light 54 channeled through the fiber optic thread 52.

The fiber optic thread 52, in a further embodiment, may be bifurcated as illustrated in FIG. 9 with a second input end being coupled to an artificial light source 44 so as to enable supplementation of the ambient light 54 with artificial light 56 generated by the artificial light source 44. The artificial light source 44 is furthermore shown to be coupled to a controller 58, which is in turn coupled to a further ambient light sensor 60 that is exposed to ambient light through a further opening 62 defined in the body 12. The controller 58 operationally receives a signal from the ambient light sensor 60 indicative of the intensity of the ambient light 54. Based on this received signal, the controller 58 makes a determination as to whether the intensity of the ambient light 54 is below a minimum threshold. If so, the controller 58 operates to activate the artificial light source 44 to generate the artificial light, thereby to supplement the ambient light with which the light sensor 38 is illuminated via the fiber optic thread 52.

In another embodiment, a separate ambient light sensor 60 need not be provided, and the controller 58 may be coupled to receive a signal indicative of the intensity of the ambient light 54 directly from the light sensor 38, or a collection of light sensors 38. In this embodiment, a closed-loop control circuit is effectively established to ensure that the light sensor 38 is sufficiently illuminated.

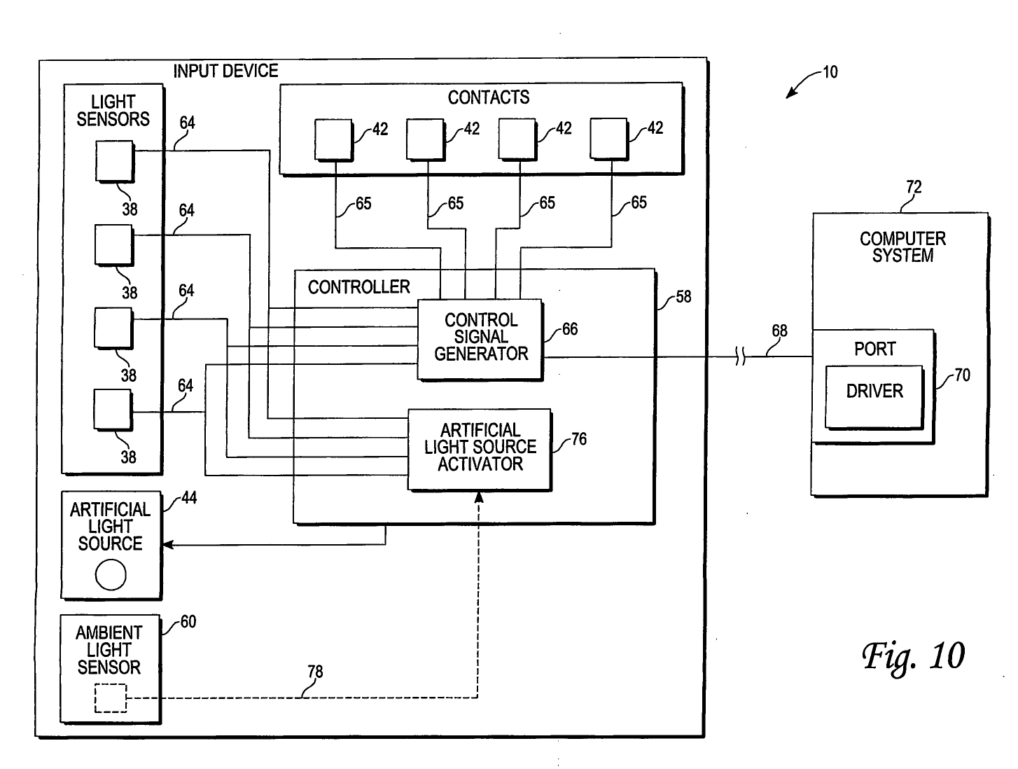

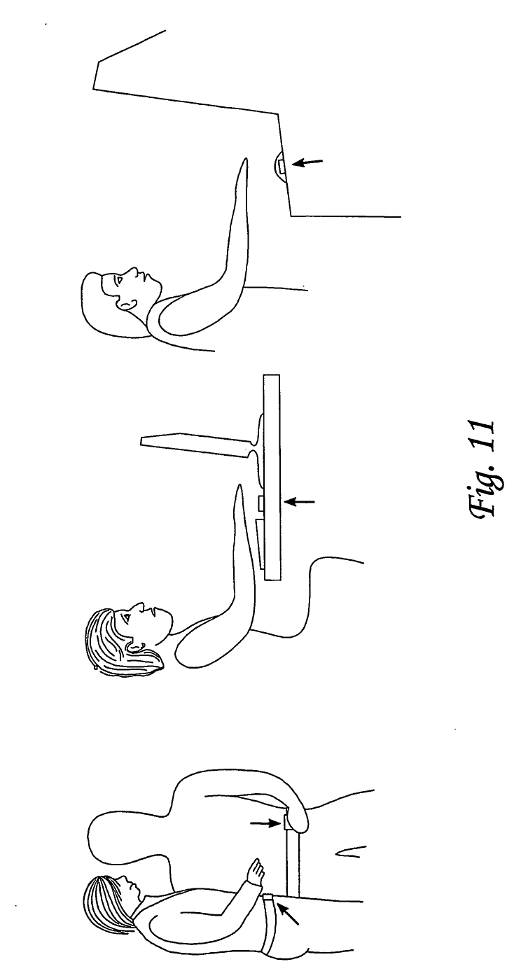

FIG. 10 is a block diagram illustrating the components of the input device 10, according to one embodiment of the present invention. The components of the input device 10 are shown to include an array of light sensors 38, each of which is coupled to provide an intensity signal 64 to a controller 58. The input device 10 also includes an array of contacts 42 that each provide a contact signal 65 to the controller 58.

The controller 58, in turn, includes a control signal generator 66 that receives the various intensity signals 64 from the light sensors 38, and the contact signals 65 from the contacts 42, and generates an input signal 68 to a port 70 of a computer system 72. The port 70 includes a driver 74 that interprets the received input signals 68 into a command to be communicated to an application executing on the computer system 72, for example. The control signal generator 66 may be implemented as software, hardware, firmware or some combination within the controller 58.

The control signal generator 66 may, in various embodiments, generate a wide range of input signals 68 to the computer system 72 based on the intensity and contact signals 64 and 65 that provide as input thereto. Various combinations and permutations of the various signals, as well as timing events related to changes in (or the provision of) the signal 64 and 65 may be interpreted by the control signal generator 66 to generate multiple input signals 68 to the computer system 72. Furthermore, the control signal generator 66 may, in computing and generating an input signal 68, may take into account the strength of an intensity signal 64 received from one of the light sensors 38, as well as a change in one or more of the intensity signals over a period of time. For example, a rapid decrease in an intensity signal 64 from one or more of the sensors 38 may indicate a rapid gesture or a forceful input of fluid into a fluid channel 26. This rapid change in an intensity signal 64 may be interpreted by the control signal generator 66 in a specific manner to generate a specific input signal 68 to the computer system 72.

In one exemplary embodiment of the invention, each of the four light sensors 38 may be associated with a particular direction of movement (e.g., up, down, left, and right) so as to allow a user, by varying the light intensity to which a relevant sensor 38 is exposed, to control the direction of movement of a cursor across a user interface. In this embodiment, the strength of the intensity signal may be inversely proportional to the speed at which the cursor is advanced in a direction associated with the sensor. For example, if the intensity signal 64 were to be detected by the control signal generator 66 to drop to a very low level, this may indicate that a forceful fluid current has been directed through an appropriate fluid channel 26. This low level of the intensity signal 64 may accordingly be interpreted by the control signal generator 66 as signaling that a cursor should be advanced in the relevant direction at a relatively high speed.

In yet a further exemplary embodiment, the rate of change in an intensity signal 64 may result in the control signal generator 66 interpreting a different type of command, depending on the rate of change. For example, a more gradual decrease in an intensity signal 64 may be interpreted to generate an input signal 68 indicating direction movement controls for a cursor. A more rapid decrease in the intensity signal 64 may be interpreted as a selection event (e.g., a “click”), resulting in the generation of an appropriate input signal 68 to the computer system 72.

While the contacts 42 are described, in one embodiment, as being activated by movement by a movable element 28, in an alternative embodiment, these contacts 42 may be activated by buttons (not shown) located on the input device 10, these buttons being directly activated by a user. Further, a receipt of a contact signal 64 may be interpreted by the control signal generator 66 as a “mode switch” signal, whereby the input device 10 can be switched between an air-based interaction mode and a gesture-based interaction mode.

The controller 58 is also shown to include an artificial light source activator 76, which may again be implemented in software, hardware, firmware or some combination thereof. The artificial light source activator 76 receives an ambient light intensity signal 78 from the ambient light sensor 60 and, based on the strength of the signal 78, activates the artificial light source 44 in the event that the intensity of the ambient light is detected to or below a predetermined minimum threshold.

In one embodiment, the artificial light source activator 76 may be coupled to receive the intensity signal 64 from each of the light sensors 38 included in the array, and performs an averaging function with respect to the intensity signals 64. In this way, the artificial light source activator 76 is provided with a less biased reading of the intensity of the ambient light than is provided by a single light sensor 38. In one embodiment, the artificial light activator 76 may perform a cyclic sampling of the intensity signal 64 in order to calculate the average intensity of the ambient light.

Various embodiments of the present invention that had been discussed may be capable of fluid-based or gesture-based interaction, or may include the capability to be reactive to both fluid-based and gesture-based interactions by users. FIG. 11 illustrates three exemplary user scenarios in which embodiments of the input device 10 may be deployed for gesture-based interactions. FIG. 11 is a schematic diagram, firstly illustrating a user scenario in which the input device 10 is deployed as part of a user's belt, allowing the user to input signals by performing gestures as indicated by the arrows. In a second user scenario, the input device 10 may reside on a desktop, and be sensitive to user gestures that inhibit or promote the intake of ambient light into the input device 10. A third exemplary use scenario illustrated in FIG. 11 shows the deployment of an input device 11 according to one embodiment as providing input to a dedicated system or machine (e.g., a kiosk) that includes as a subcomponent a computer system.

FIG. 12 illustrates a further use scenario, in which the input device 10 may be coupled to a headset 78 so as to allow the input device 10 to be head-mounted. A head-mounted use, it will be appreciated, enables convenient inhaling and exhaling in the vicinity of the first openings 16 by a user.

The input device 10 may also include a communication circuitry (not shown) so as to enable the input device 10 to provide the input signal 68 wirelessly to the computer system 72. In one embodiment, the communication circuitry may comprise Bluetooth circuitry so as to enable communication of the input signal 68 to a Bluetooth receiver incorporated within a computer system 72.

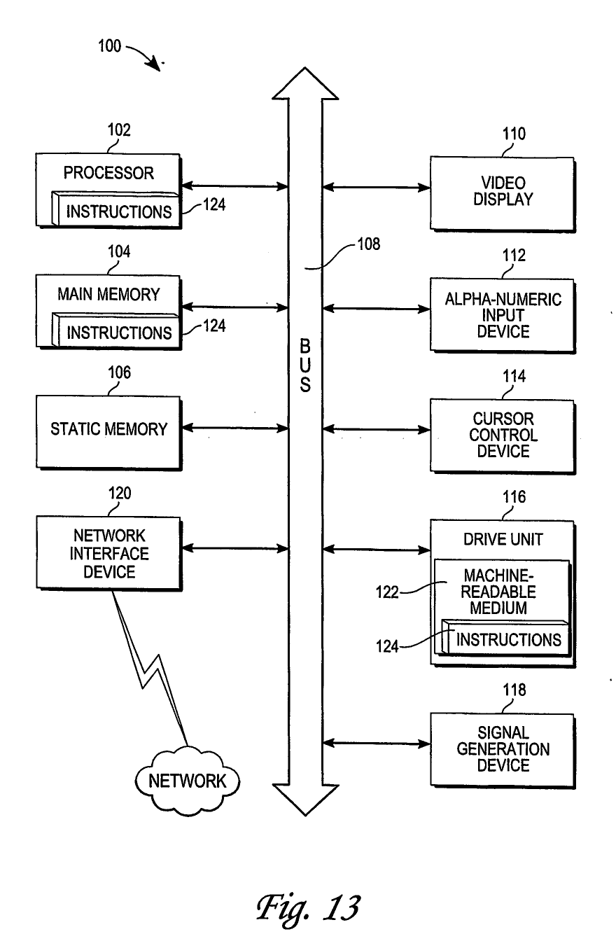

FIG. 13 shows a diagrammatic representation of machine in the exemplary form of a computer system 100 within which a set of instructions, for causing the machine to perform any one or more of the methodologies discussed herein, may be executed. In alternative embodiments, the machine operates as a standalone device or may be connected (e.g., networked) to other machines. In a networked deployment, the machine may operate in the capacity of a server or a client machine in server-client network environment, or as a peer machine in a peer-to-peer (or distributed) network environment. The machine may be the input device 10, a personal computer (PC), a tablet PC, a set-top box (STB), a Personal Digital Assistant (PDA), a cellular telephone, a web appliance, a network router, switch or bridge, or any machine capable of executing a set of instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein.

The exemplary computer system 100 includes a processor 102 (e.g., a central processing unit (CPU) a graphics processing unit (GPU) or both), a main memory 104 and a static memory 106, which communicate with each other via a bus 108. The computer system 100 may further include a video display unit 110 (e.g., a liquid crystal display (LCD) or a cathode ray tube (CRT)). The computer system 100 also includes an alphanumeric input device 112 (e.g., a keyboard), a user interface (UI) navigation device 114 (e.g., a mouse), a disk drive unit 116, a signal generation device 118 (e.g., a speaker) and a network interface device 120.

The disk drive unit 116 includes a machine-readable medium 122 on which is stored one or more sets of instructions (e.g., software 124) embodying any one or more of the methodologies or functions described herein. The software 124 may also reside, completely or at least partially, within the main memory 104 and/or within the processor 102 during execution thereof by the computer system 100, the main memory 104 and the processor 102 also constituting machine-readable media.

The software 124 may further be transmitted or received over a network 126 via the network interface device 120.

While the machine-readable medium 192 is shown in an exemplary embodiment to be a single medium, the term “machine-readable medium” should be taken to include a single medium or multiple media (e.g., a centralized or distributed database, and/or associated caches and servers) that store the one or more sets of instructions. The term “machine-readable medium” shall also be taken to include any medium that is capable of storing, encoding or carrying a set of instructions for execution by the machine and that cause the machine to perform any one or more of the methodologies of the present invention. The term “machine-readable medium” shall accordingly be taken to included, but not be limited to, solid-state memories, optical and magnetic media, and carrier wave signals.

Thus, an input device for a computer system, the input device utilizing ambient light to generate input signals to a computer system, and their method of manufacturing the same have been described. Although the present invention has been described with reference to specific exemplary embodiments, it will be evident that various modifications and changes may be made to these embodiments without departing from the broader spirit and scope of the invention. Accordingly, the specification and drawings are to be regarded in an illustrative rather than a restrictive sense.

The various embodiments of the input device 10 described above are advantageous in that they allow a user to provide input to a computer system without requiring that the user physically and directly manipulate the input device 10 itself, or any component thereof. This may be particularly advantageous where it is inconvenient for the user to perform such a physical manipulation (e.g., where the user's hands are unavailable to perform such manipulation).

The present invention also extends to a method of manufacturing an input device 10, for example according to any one of the various exemplary embodiments discussed above. Specifically, a method of manufacturing includes a forming the body 12, defining a plurality of fluid channels 26 in the body 12, locating a respective light sensor 38 within each of the fluid channels 26, and locating a movable element 28 within each of the fluid channels 26 so that the movable element is movable between a first position in which an associated light sensor 38 is illuminated by light (either ambient or internally generated) of a first intensity and a second position in which the associated light sensor 38 is illuminated by light of a second intensity. Optionally, an artificial light source 24 may also be located within a fluid channel 26 associated with each light sensor 38 to supplement ambient light with which the light sensitive 38 may be illuminated. A number of openings (e.g., windows) are also defined within the body 12, and the light sensors 38 are located within the body 12 so as to be illuminated by ambient light received into the body 12 through the openings.

In the present invention also extends to a kit including a computer system, or a device including a computer system, and an input device 10 according to the present invention.

1. An input device to provide input to a computer system, the input device comprising:
a body defining a fluid channel;
a movable element located to be movable responsive to a fluid flow through the fluid channel; and
a light sensor located such that movement of the movable element varies an intensity of light with which the light sensor is illuminated, the light sensor being to generate an input signal in accordance with the intensity of the light with which the light sensor is illuminated.

2. The device of claim 1, wherein the body defines a plurality of fluid channels, the device further including:
a plurality of movable elements, each of the plurality of movable elements being associated with a respective one of the plurality of fluid channels and being movable responsive to a fluid flow through the respective one of the plurality of channels; and
a plurality of light sensors, each of the plurality of light sensors being associated with a respective one of the plurality of movable elements such that movement of the respective movable element varies an intensity of light with which the light sensor is illuminated, each of the plurality of light sensors being able to generate one of a plurality of input signals in accordance with the intensity of the light with which the respective light sensor is illuminated, each of the plurality of input signals operationally providing a distinct input to a computer system.

3. The device of claim 1, wherein the movable element is located within the fluid channel so as to be movable responsive to the fluid flow therethrough.

4. The device of claim 1, wherein the movable element is secured to the body at a fixed end thereof so as to be pivotably movable within the fluid channel.

5. The device of claim 1, wherein the body defines an inlet opening and an exhaust opening for the fluid channel.

6. The device of claim 1, wherein the body defines an opening through which the light sensor is operationally illuminated with ambient light, and the light sensor is located such that the movement of the movable element varies an intensity of ambient light with which the light sensor is illuminated.

7. The device of claim 1, including a light channel operationally to channel the ambient light through the opening to illuminate the light sensor.

8. The device of claim 7, wherein the light channel comprises a light-conductive material.

9. The device of claim 8, wherein the light-conductive material comprises a fiber optic thread.

10. The device of claim 6, including a window that is located in the opening through which the light sensor is operationally illuminated with the ambient light.

11. The device of claim 1, including an artificial light source operationally to supplement the ambient light.

12. The device of claim 11, including an ambient light sensor operationally to sense an intensity of the ambient light, and a controller to activate the artificial light sensor when the intensity of the ambient light, as sensed by the ambient light sensor, is below a predetermined minimum.

13. The device of claim 11, wherein the artificial light source is operationally to supplement the ambient light in accordance with a measured intensity of the ambient light.

14. The device of claim 11, wherein the artificial light source is operationally to supplement the ambient light so as to illuminate the light sensor with a combined intensity above a predetermined minimum intensity.

15. An input device to provide input to a computer system, the input device comprising:
a plurality of light sensors, each to generate a discrete output, and arranged operationally to be illuminated by ambient light; and
a controller, coupled to each of the plurality of light sensors, and operationally to generate an input to a computer system based on at least one discrete output received from the plurality of light sensors.

16. The input device of claim 15, including a body to which each of the plurality of light sensors is attached.

17. The input device of claim 16, wherein each of the plurality of light sensors is accommodated within the body.

18. The input device of claim 15, wherein the body defines at least one opening through which at least one of the plurality of light sensors is operationally illuminated by the ambient light.

19. The input device of claim 18, including a light channel through which the ambient light is operationally channelled, through the at least one opening, to illuminate the at least one of the plurality of light sensors.

20. The input device of claim 19, wherein the light channel comprises a light-conductive material.

21. The input device of claim 20, wherein the light-conductive material comprises a fiber optic thread.

22. The input device of claim 17, wherein each of the plurality of light sensors is housed within a respective chamber defined within the body, and each of the chambers is provided with an opening through which a respective one of the plurality of light sensors is operationally illuminated by the ambient light.

23. A method of manufacturing an input device according to any one of the preceding claims.

24. A kit including an input device according to any one of the preceding claims, and a computer system.
